(19) United States
(12) Patent Application Publication
(10) Pub. No.: US 2026/0282865 A1
(43) Pub. Date: Sep. 17, 2026

(54) STACKED MEMORY DEVICES

(71) Applicant: SK hynix Inc., Icheon-si Gyeonggi-do (KR)

(72) Inventor: Dong Keun KIM, Icheon-si Gyeonggi-do (KR)

(73) Assignee: SK hynix Inc., Icheon-si Gyeonggi-do (KR)

(21) Appl. No.: 19/268,393

(22) Filed: Jul. 14, 2025

(30) Foreign Application Priority Data
Mar. 17, 2025 (KR) 10-2025-0034300

(51) Int. Cl. H10W 20/20; H10B 80/00; H10D 80/30; H10W 90/00; H10W 72/00; H10W 72/30; H10W 90/20

(52) U.S. Cl. CPC H10W 20/20; H10B 80/00; H10D 80/30; H10W 90/00; H10W 72/07354; H10W 72/341; H10W 72/877; H10W 90/20; H10W 90/297; H10W 90/722

(57) ABSTRACT

A stacked memory device includes a plurality of core dies stacked over a base die, and a power supply wire stacked over the plurality of core dies. Each of the plurality of core dies includes a core connection circuit including a core interconnection and a through via set, and an isolated connection circuit that is isolated from the core connection circuit and transmits a power supply voltage.

The present application claims priority under 35 U.S.C §119(a) to Korean Application No. 10-2025-0034300, filed in the Korean Intellectual Property Office on March 17, 2025, the entire contents of which application is incorporated herein by reference.

### BACKGROUND

### 1. Technical Field

The present disclosure relates to stacked memory devices that supplies a power supply voltage stably.

### 2. Related Art

Stacked memory systems such as high bandwidth memory (HBM) devices are used in a wide range of applications due to their high bandwidth and energy efficiency. Unlike conventional memory systems that use parallel data buses, the stacked memory systems include a stacked memory device including a base chip and a plurality of memory chips interconnected by through silicon vias (TSVs). The stacked memory device includes a physical interface, such as a physical layer for communication with a processor. The physical layer is designed for high-speed data transmission and efficient communication.

### SUMMARY

The present disclosure describes a stacked memory device that may include a plurality of core dies stacked over a base die, and a power supply wire stacked over the plurality of core dies. Each of the plurality of core dies may include a core connection circuit including a core interconnection and a core through via set, and an isolated connection circuit that is isolated from the core connection circuit and transmits a power supply voltage.

The present disclosure describes an internal voltage generation circuit that may include a plurality of core dies stacked over a base die, and a power supply wire stacked over the plurality of core dies. The base die may include a base connection circuit comprising a base interconnection and a base through via set, and a base isolated connection circuit that is separated from the base connection circuit and transmits a power supply voltage. Each of the plurality of core dies may include a core connection circuit comprising a core interconnection and a core through via set, and an isolated connection circuit that is separated from the core connection circuit and transmits the power supply voltage.

The present disclosure describes an internal voltage generation circuit that may include a plurality of core dies stacked over a base die. The base die may include a base connection circuit comprising a base interconnection and a base through via set, and a base isolated connection circuit that is separated from the base connection circuit and transmits a power supply voltage.

### BRIEF DESCRIPTION OF THE DRAWINGS

FIG. 1 illustrates a stacked memory device according to an embodiment of the present disclosure.

FIG. 2 illustrates a side of a first isolated connection circuit according to an embodiment of the present disclosure.

FIG. 3 illustrates a stacked memory device according to an embodiment of the present disclosure.

FIG. 4 illustrates a stacked memory device according to an embodiment of the present disclosure.

FIG. 5 is a block diagram illustrating a memory system according to an embodiment of the present disclosure.

### DETAILED DESCRIPTION

Terms such as “first” and “second” are used to distinguish between various elements and do not imply size, order, priority, quantity, or importance of the elements. For example, a first element may be named as a second element in one example, and the second element may be named as a first element in another example.

When one component is identified as “connected” to another component, the components may be connected directly or through an intervening component between the components. When two components are identified as “directly connected,” one component is directly connected to the other component without an intervening component between the two components.

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

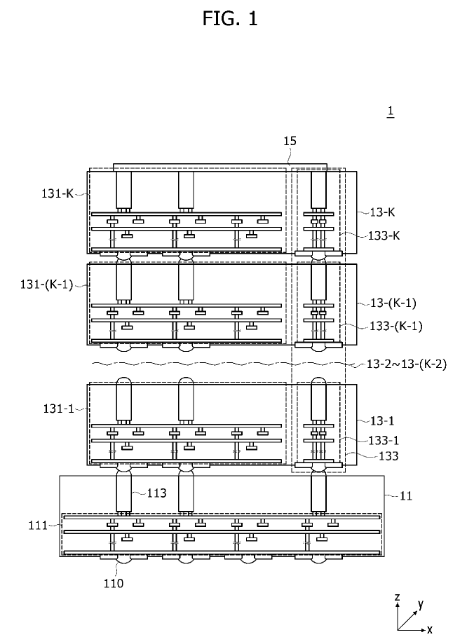

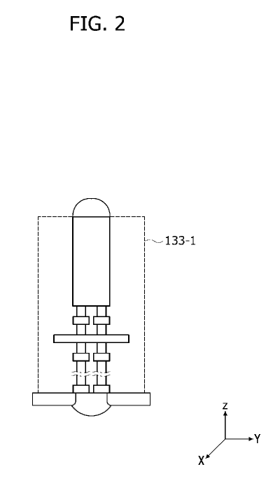

FIG. 1 illustrates a stacked memory device 1 according to an embodiment of the present disclosure. FIG. 2 illustrates a first isolated connection circuit 133-1 according to an embodiment of the present disclosure.

As shown in FIG. 1, the stacked memory device 1 includes a base die 11, a first core die 13-1 to a K^{th} core die 13-K, and a power supply wire 15.

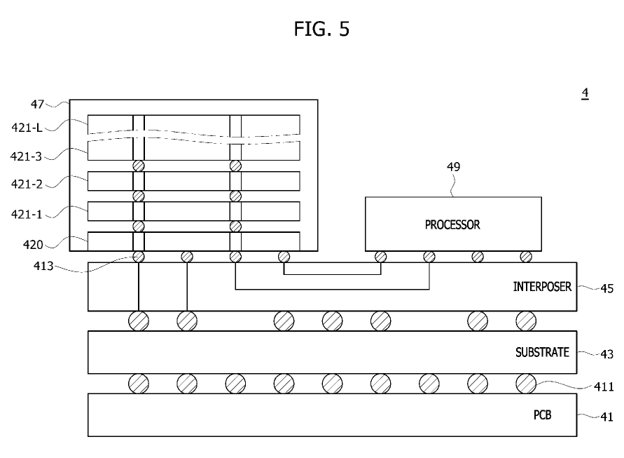

The base die 11 is stacked over an interposer (for example, an interposer 45 as shown in FIG. 5) or over a substrate (for example, a substrate 43 as shown in FIG. 5) with pads (for example, pads 110 in FIG. 1) therebetween. The pads are implemented with bump pads or micro-bump pads. The base die 11 includes a base interconnection 111 and a base through via set. The base interconnection 111 includes a plurality of metal layers. The plurality of metal layers included in the base interconnection 111 includes a first metal layer directly connected to a gate, a source, and a drain of a transistor, a second metal layer and a third metal layer connected to the first metal layer using vias, and so forth. The first metal layer, the second metal layer, and the third metal layer are disposed in a first direction (x-direction) or a second direction (y-direction) and are stacked in a third direction (z-direction). The base interconnection 111 transmits or transfers various electrical signals including a power supply voltage (Voltage Drain Drain, VDD), commands, addresses, and control signals supplied from the substrate, for example, the substrate 43 in FIG. 5, to the first core die 13-1 using the base interconnection 111 and the base through via set. The base through via set includes a plurality of through vias, for example, through vias 113. The base through via set is connected to the first core die 13-1 through pads between the base interconnection 111 and the first core die 13-1.

The first core die 13-1 is stacked in the third direction (z-direction) in relation to the base die 11 and connected to each other through pads therebetween. The first core die 13-1 includes a first core connection circuit 131-1 and a first isolated connection circuit 133-1. The first core connection circuit 131-1 includes a first core interconnection and a first core through via set that are connected to the second core die 13-2 and the base die 11 through pads. The first core interconnection includes a plurality of metal layers, and the first core through via set includes a plurality of through vias. The first core connection circuit 131-1 transmits or transfers various electrical signals including commands, addresses, control signals, and a power supply voltage using the first core interconnection and the first core through via set. The first isolated connection circuit 133-1 includes a first isolated interconnection and a first isolated through via set that are connected to the second core die 13-2 and the base die 11 through pads. The first isolated interconnection includes a plurality of metal layers, and the first isolated through via includes a plurality of through vias. The first isolated connection circuit 133-1 transmits or transfers the power supply voltage, supplied from the base die 11, to the second core die 13-2 using the first isolated interconnection and the first isolated through via. The first isolated connection circuit 133-1 is separated from the first core connection circuit 131-1 and stably supplies the power supply voltage to the second core die 13-2. The power supply voltage may be an input/output power voltage (VDDQ) that is a voltage supplied to a buffer that transmits data. The first isolated interconnection included in the first isolated connection circuit 133-1 is disposed in the first direction (x-direction) and the second direction (y-direction), and the three-dimensional nature of the first isolated interconnection included in the first isolated connection circuit 133-1 is illustrated in FIG. 2, which is a side view of the first isolated interconnection 133-1 in FIG. 1.

The (K-1) core die 13-(K-1) is stacked in the third direction (z-direction) in relation to a (K-2) core die 13-(K-2) and connected to each other through pads therebetween, where K is a natural number greater than or equal to 3. The (K-1) core die 13-(K-1) includes a (K-1) core connection circuit 131-(K-1) and a (K-1) isolated connection circuit 133-(K-1). The (K-1) core connection circuit 131-(K-1) includes a (K-1) core interconnection and a (K-1) core through via set that are connected to the K^{th} core die 13-K and the (K-2) core die 13-(K-2) through pads. The (K-1) core interconnection includes a plurality of metal layers, and the (K-1) core through via set includes a plurality of through vias. The (K-1) core connection circuit 131-(K-1) transmits or transfers various electrical signals including commands, addresses, control signals, and a power supply voltage using the (K-1) core interconnection and the (K-1) core through via. The (K-1) isolated connection circuit 133-(K-1) includes a (K-1) isolated interconnection and a (K-1) isolated through via that are connected to the K^{th} core die 13-K and the (K-2) core die 13-(K-2) through pads. The (K-1) isolated interconnection includes a plurality of metal layers, and the (K-1) isolated through via includes a plurality of through vias. The (K-1) isolated connection circuit 133-(K-1) transmits or transfers the power supply voltage, supplied from the (K-2) core die 13-(K-2), to the K^{th} core die 13-K using the (K-1) isolated interconnection and the (K-1) isolated through via. The (K-1) isolated connection circuit 133-(K-1) is isolated from the (K-1) core connection circuit 131-(K-1) and stably supplies the power supply voltage to the K^{th} core die 13-K.

The K^{th} core die 13-K is stacked in the third direction (z-direction) in relation to the (K-1) core die 13-(K-1) and connected to each other through pads therebetween. The K^{th} core die 13-K includes a K^{th} core connection circuit 131-K and a K^{th} isolated connection circuit 133-K. The K^{th} core connection circuit 131-K includes a K^{th} core interconnection and a K^{th} core through via set that are connected to the power supply wire 15 and the (K-1) core die 13-(K-1) through pads. The K^{th} core interconnection includes a plurality of metal layers, and the K^{th} core through via set includes a plurality of through vias. The K^{th} core connection circuit 131-K transmits or transfers various electrical signals including commands, addresses, control signals, and a power supply voltage through using the K^{th} core interconnection and the K^{th} core through via set. The K^{th} isolated connection circuit 133-K includes a K^{th} isolated interconnection and a K^{th} isolated through via that are connected to the power supply wire 15 and the (K-1) core die 13-(K-1) through pads. The K^{th} isolated interconnection includes a plurality of metal layers, and the K^{th} isolated through via includes a plurality of through vias. The K^{th} isolated connection circuit 133-K transmits or transfers the power supply voltage, supplied from the (K-1) core die 13-(K-1), to the power supply wire 15 using the K^{th} isolated interconnection and the K^{th} isolated through via. The K^{th} isolated connection circuit 133-K is isolated from the K^{th} core connection circuit 131-K and stably supplies the power supply voltage to the power supply wire 15.

The power supply wire 15 is stacked in the third direction (z-direction) in relation to the K^{th} core die 13-K. The power supply wire 15 sequentially transmits the power supply voltage, supplied from the K^{th} core die 13-K, to each of the K^{th} core die 13-K to the first core die 13-1 in an opposite direction to the third direction (-z-direction) through the K^{th} core connection circuit 131-K to the first core connection circuit 131-1, respectively. The first core die 13-1 to the K^{th} core die 13-K receive the power supply voltage supplied from the power supply wire 15 through the first core connection circuit 131-1 to K^{th} core connection circuit 131-K, respectively, the power supply wire 15 being supplied with the power supply voltage from the base die 11 through the isolated connection circuit 133. The isolated connection circuit 133 includes the first isolated connection circuit 133-1 to the K^{th} isolated connection circuit 133-K.

In the first core die 13-1 to the K^{th} core die 13-K, the farther the core die is from the base die 11 in the third direction (z-direction), the more difficult it is for the base die 11 to stably supply it with the power supply voltage. The stacked memory device 1 of the present disclosure includes the first core die 13-1 to the K^{th} core die 13-K, each including the first isolated connection circuit 133-1 to the K^{th} isolated connection circuit 133-K that are separated and isolated from the first core connection circuit 131-1 to the K^{th} core connection circuit 131-K, respectively. The stacked memory device 1 of the present disclosure supplies the power supply voltage in the third direction (z-direction) through the first isolated connection circuit 133-1 to the K^{th} isolated connection circuit 133-K and supplies the power supply voltage in a fourth direction (-z-direction) to the first core die 13-1 from the K^{th} core die 13-K through the power supply wire 15, thereby stably supplying the power supply voltage to each of the first core die 13-1 to the K^{th} core die 13-K even when the number K of core dies increases.

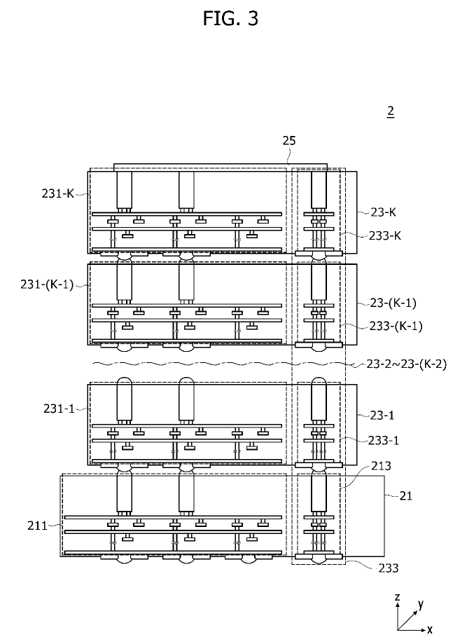

FIG. 3 illustrates a stacked memory device 2 according to an embodiment of the present disclosure.

As shown in FIG. 3, the stacked memory device 2 includes a base die 21, a first core die 23-1 to a K^{th} core die 23-K, and a power supply wire 25.

The base die 21 is stacked over an interposer (for example, an interposer 45 in FIG. 5) or a substrate (for example, a substrate 43 in FIG. 5) with pads therebetween. The pads include bump pads or micro-bump pads. The base die 21 includes a base connection circuit 211 and a base isolated connection circuit 213. The base connection circuit 211 includes a base interconnection and a base through via set that are connected to the first core die 23-1 through pads. The base interconnection includes a plurality of metal layers, and the base through via set includes a plurality of through vias. The base connection circuit 211 transmits or transfers various electrical signals including commands, addresses, control signals, and a power supply voltage to the first core die 23-1. The base isolated connection circuit 213 includes a base isolated interconnection and a base isolated through via that are connected to the first core die 23-1 through pads. The base isolated interconnection includes a plurality of metal layers, and the base isolated through via includes a plurality of through vias. The base isolated connection circuit 213 transmits or transfers the power supply voltage supplied from the substrate to the first core die 23-1 using the base isolated interconnection and the base isolated through via. The base isolated connection circuit 213 is isolated from the base connection circuit 211 and stably supplies the power supply voltage to the first core die 23-1.

The first core die 23-1 is stacked in a third direction (z-direction) in relation to the base die 21 and connected to each other through pads therebetween. The first core die 23-1 includes a first core connection circuit 231-1 and a first isolated connection circuit 233-1. The first core connection circuit 231-1 includes a first core interconnection and a first core through via set that are connected to the second core die 23-2 and the base die 21 through pads. The first core interconnection includes a plurality of metal layers, and the first core through via set includes a plurality of through vias. The first core connection circuit 231-1 transmits or transfers various electrical signals including commands, addresses, control signals, and a power supply voltage to the base die 21 or the second core die 23-2 using the first core interconnection and the first core through via set. The first isolated connection circuit 233-1 includes a first isolated interconnection and a first isolated through via that are connected to the second core die 23-2 and the base die 21 through pads. The first isolated interconnection includes a plurality of metal layers, and the first isolated through via includes a plurality of through vias. The first isolated connection circuit 233-1 transmits or transfers the power supply voltage supplied from the base die 21 to the second core die 23-2 using the first isolated interconnection and the first isolated through via. The first isolated connection circuit 233-1 is isolated from the first core connection circuit 231-1 and stably supplies the power supply voltage to the second core die 23-2. The power supply voltage may be an input/output power voltage (VDDQ) supplied to a buffer that transmits data.

The (K-1) core die 23-(K-1) is stacked in the third direction (z-direction) in relation to the (K-2) core die 23-(K-2) and connected to each other through pads therebetween, where K is a natural number greater than or equal to 3. The (K-1) core die 23-(K-1) includes a (K-1) core connection circuit 231-(K-1) and a (K-1) isolated connection circuit 233-(K-1). The (K-1) core connection circuit 231-(K-1) includes a (K-1) core interconnection and a (K-1) core through via set that are connected to the K^{th} core die 23-K and the (K-2) core die 23-(K-2) through pads. The (K-1) core interconnection includes a plurality of metal layers, and the (K-1) core through via set includes a plurality of through vias. The (K-1) core connection circuit 231-(K-1) transmits or transfers various electrical signals including commands, addresses, control signals, and a power supply voltage using the (K-1) core interconnection and the (K-1) core through via set. The (K-1) isolated connection circuit 233-(K-1) includes a (K-1) isolated interconnection and a (K-1) isolated through via that are connected to the K^{th} core die 23-K and the (K-2) core die 23-(K-2) through pads. The (K-1) isolated interconnection includes a plurality of metal layers, and the (K-1) isolated through via includes a plurality of through vias. The (K-1) isolated connection circuit 233-(K-1) transmits or transfers the power supply voltage, supplied from the (K-2) core die 23-(K-2), to the K^{th} core die 23-K using the (K-1) isolated interconnection and the (K-1) isolated through via. The (K-1) isolated connection circuit 233-(K-1) is isolated from the (K-1) core connection circuit 231-(K-1) and stably supplies the power supply voltage to the K^{th} core die 23-K.

The K^{th} core die 23-K is stacked in the third direction (z-direction) in relation to the (K-1) core die 23-(K-1) and connected to each other through pads therebetween. The K^{th} core die 23-K includes a K^{th} core connection circuit 231-K and a K^{th} isolated connection circuit 233-K. The K^{th} core connection circuit 231-K includes a K^{th} core interconnection and a K^{th} core through via set that are connected to the power supply wire 25 and the (K-1) core die 23-(K-1) through pads. The K^{th} core interconnection includes a plurality of metal layers, and the K^{th} core through via set includes a plurality of through vias. The K^{th} core connection circuit 231-K transmits or transfers various electrical signals including commands, addresses, control signals, and a power supply voltage using the K^{th} core interconnection and the K^{th} core through via set. The K^{th} isolated connection circuit 233-K includes a K^{th} isolated interconnection and a K^{th} isolated through via that are connected to the power supply wire 25 and the (K-1) core die 23-(K-1) through pads. The K^{th} isolated interconnection includes a plurality of metal layers, and the K^{th} isolated through via includes a plurality of through vias. The K^{th} isolated connection circuit 233-K transmits or transfers the power supply voltage, supplied from the (K-1) core die 23-(K-1), to the power supply wire 25 using the K^{th} isolated interconnection and the K^{th} isolated through via. The K^{th} isolated connection circuit 233-K is isolated from the K^{th} core connection circuit 231-K and stably supplies the power supply voltage to the power supply wire 25.

The power supply wire 25 is stacked in the third direction (z-direction) in relation to the K^{th} core die 23-K. The power supply wire 25 sequentially transmits the power supply voltage supplied from the K^{th} core die 23-K to each of the K^{th} core die 23-K to the first core die 23-1 in an opposite direction to the third direction (-z-direction) through the K^{th} core connection circuit 231-K to the first core connection circuit 231-1, respectively. The first core die 23-1 to the K^{th} core die 23-K receive the power supply voltage supplied from the power supply wire 25 through the first core connection circuit 231-1 to K^{th} core connection circuit 231-K, respectively, the power supply wire 25 being supplied with the power supply voltage from the base die 21 through the isolated connection circuit 233. The isolated connection circuit 233 includes the base isolated connection circuit 213 and the first isolated connection circuit 233-1 to the K^{th} isolated connection circuit 233-K.

In the first core die 23-1 to the K^{th} core die 23-K, the farther the core die is from the base die 21 in the third direction (z-direction), the more difficult it is for the base die 21 to stably supply it with the power supply voltage. The stacked memory device 2 of the present disclosure includes the first core die 23-1 to the K^{th} core die 23-K, each including the first isolated connection circuit 233-1 to the K^{th} isolated connection circuit 233-K that are separated and isolated from the first core connection circuit 231-1 to the K^{th} core connection circuit 231-K, respectively. The stacked memory device 2 of the present disclosure supplies the power supply voltage in the third direction (z-direction) through the first isolated connection circuit 233-1 to the K^{th} isolated connection circuit 233-K, and supplies the power supply voltage in a fourth direction (-z-direction) to the first core die 23-1 from the K^{th} core die 23-K through the power supply wire 25, thereby stably supplying the power supply voltage to the first core die 23-1 to the K^{th} core die 23-K even when the number K of core dies increases.

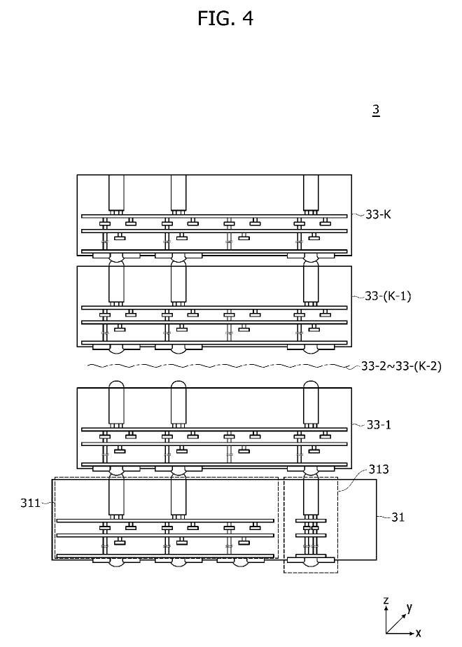

FIG. 4 illustrates a stacked memory device 3 according to an embodiment of the present disclosure.

As shown in FIG. 4, the stacked memory device 3 includes a base die 31, a first core die 33-1 to a K^{th} core die 33-K, and a power supply wire 25.

The base die 31 is stacked over an interposer (for example, an interposer 45 in FIG. 5) or a substrate (for example, a substrate 43 in FIG. 5) with pads therebetween. The pads may be bump pads or micro-bump pads. The base die 31 includes a base connection circuit 311 and a base isolated connection circuit 313. The base connection circuit 311 includes a base interconnection and a base through via set that are connected to the first core die 33-1 through pads. The base interconnection includes a plurality of metal layers, and the base through via set includes a plurality of through vias. The base connection circuit 311 transmits or transfers various electrical signals including commands, addresses, control signals, and a power supply voltage to the first core die 33-1 using the base interconnection and the base through via set. The base isolated connection circuit 313 includes a base isolated interconnection and a base isolated through via that are connected to the first core die 33-1 through pads. The base isolated interconnection includes a plurality of metal layers, and the base isolated through via includes a plurality of through vias. The base isolated connection circuit 313 transmits the power supply voltage supplied from the substrate to the first core die 33-1 using the base isolated interconnection and the base isolated through via. The base isolated connection circuit 313 is isolated from the base connection circuit 311 and stably supplies the power supply voltage to the first core die 33-1.

The first core die 33-1 is stacked in a third direction (z-direction) in relation to the base die 31 and connected to each other through pads therebetween. The first core die 33-1 includes a first core interconnection and a first core through via set. The first core interconnection includes a plurality of metal layers, and the first core through via set includes a plurality of through vias. The first core die 33-1 transmits or transfers various electrical signals including commands, addresses, control signals, and a power supply voltage to the base die 31 or the second core die 33-2 using the first core interconnection and the first core through via set. The power supply voltage may be an input/output power voltage (VDDQ) that is a voltage supplied to a buffer that transmits data.

The (K-1) core die 33-(K-1) is stacked in the third direction (z-direction) in relation to the (K-2) core die 33-(K-2) and connected to each other through pads therebetween, where K is a natural number greater than or equal to 3. The (K-1) core die 33-(K-1) includes a (K-1) core interconnection and a (K-1) core through via set. The (K-1) core interconnection includes a plurality of metal layers, and the (K-1) core through via set includes a plurality of through vias. The (K-1) core die 33-(K-1) transmits or transfers various electrical signals including commands, addresses, control signals, and a power supply voltage to the (K-2) core die 33-(K-2) or the K^{th} core die 33-(K) using the (K-1) core interconnection and the (K-1) core through via set.

The K^{th} core die 33-K is stacked in the third direction (z-direction) in relation to the K^{th} core die 33-(K-1) and connected to each other through pads therebetween. The K^{th} core die 33-K includes a K^{th} core interconnection and a K^{th} core through via set. The K^{th} core interconnection includes a plurality of metal layers, and the K^{th} core through via set includes a plurality of through vias. The K^{th} core die 33-K transmits or transfers various electrical signals including commands, addresses, control signals, and a power supply voltage to the (K-1) core die 33-(K-1) using the K^{th} core interconnection and the K^{th} core through via set.

In the first core die 33-1 to the K^{th} core die 33-K, the farther the core die is from the base die 31 in the third direction (z-direction), the more difficult it is for the base die 31 to stably supply it with the power supply voltage. The stacked memory device 3 of the present disclosure supplies the power supply voltage in the third direction (z-direction) to the base die 31 through the base isolated connection circuit 313 that is separated and isolated from the base connection circuit 311, thereby stably supplying the power supply voltage to each of the first core die 33-1 to the K^{th} core die 33-K even when the number K of core dies increases.

FIG. 5 is a block diagram illustrating a memory system 4 according to an embodiment of the present disclosure.

As shown in FIG. 5, the memory system 4 includes a printed circuit board (PCB) 41, a substrate 43, an interposer 45, a memory device 47, and a processor 49.

The printed circuit board 41 connects various electronic components to each other to form electronic circuits. The electronic circuits include the memory system 4. A copper (Cu) layer, a solder mask, a silk screen, and so forth are formed on the printed circuit board 41. Circuit paths that transmit or transfer signals or power are formed in the copper (Cu) layer. The solder mask prevents damage to the circuits and protects a specific region in which components are soldered. The silk screen indicates the location or information for the electronic components as characters or symbols printed on a surface of the printed circuit board 41.

The substrate 43 is disposed over the printed circuit board 41 with bump pads therebetween (for example, bump pads 411) and mechanically supports the interposer 45, the memory device 47, and the processor 49. The substrate 43 functions as a physical base for the printed circuit board 41 and is an insulator. The substrate 43 may include materials, such as FR4 that is an insulator made of fiberglass and epoxy resin; ceramics that can withstand high temperatures, have appropriate thermal conductivity properties, and are used in high-frequency circuits; polyimide that is used as a basic material for flexible PCBs due to flexible characteristics; and the like.

The interposer 45 is disposed over the substrate 43 with bump pads therebetween and includes wires that connect electronic components (for example, the memory device 47 and the processor 49) that have form factors or pin arrangements that do not match or have different spacing. The interposer 45 converts signals from different interfaces, such as DDR, HBM, PCle.

The memory device 47 is disposed over the interposer 45 with pads therebetween (for example, micro-bump pads 413). The memory device 47 stores data received from the processor 49 or outputs the stored data to the processor 49 under the control of the processor 49. The memory device 47 includes a base die 420 and a plurality of core dies 421-1 to 421-L, where L is an integer greater than 1. The core dies 421-1 to 421-L are stacked over the base die 420 with micro-bump pads therebetween. The base die 420 and the core dies 421-1 to 421-L are vertically connected to each other using through vias and micro-bump pads. The base die 420 controls efficient data transmission between the processor 49 and the core dies 421-1 to 421-L. The base die 420 receives input/output power supply voltage (voltage drain drain for IO also referred to as output stage drain power voltage) VDDQ as an operating voltage utilized during the operation of internal circuits included in the base die 420. The base die 420 receives the input/output power voltage VDDQ from the printed circuit board 41 through the substrate 43 and the interposer 45. The input/output power voltage VDDQ is a voltage supplied to buffers that transmit data and is distinguished or different from the power supply voltage VDD. The core dies 421-1 to 421-L use a peripheral voltage VPERI as an operating voltage during the operation of the internal circuits included in the core dies 421-1 to 421-L. The core dies 421-1 to 421-L generate the peripheral voltage VPERI from the input/output power supply voltage VDD received through the base die 420. The core dies 421-1 to 421-L generate the peripheral voltage VPERI at a lower voltage level than the input/output power voltage VDDQ and use the peripheral voltage VPERI as an operating voltage. Each of the core dies 421-1 to 421-L includes a plurality of channel regions, for example, eight channel regions or sixteen channel regions that operate independently. Each of the plurality of channel regions is allocated with a channel operating independently to receive or transmit data. The number L of core dies 421-1 to 421-L may be four, eight, twelve, sixteen, and so forth. For example, when each of the core dies 421-1 to 421-12has eight channels, the core dies 421-1 to 421-4, the core dies 421-5 to 421-8, and the core dies 421-9 to 421-12 each include thirty-two channel regions and transmit and receive data to and from the processor 49 in units of a rank including thirty-two channels.

The memory device 47 is implemented with the stacked memory device 1 shown in FIG. 1, the stacked memory device 2 shown in FIG. 3, and the stacked memory device 3 shown in FIG. 4. The memory device 47 isolates the power wiring circuit that supplies power supply voltage from other wiring circuits and can stably supply power supply voltage to core dies.

Concepts are disclosed in conjunction with various examples and embodiments. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. The scope of the present disclosure is not limited to the descriptions. All changes within the meaning and range of equivalency of the claims are included within their scope.

What is claimed is:

1. A stacked memory device comprising:
a plurality of core dies stacked over a base die; and
a power supply wire stacked over the plurality of core dies,
wherein each of the plurality of core dies comprises:
a core connection circuit including a core interconnection and a core through via set; and
an isolated connection circuit that is isolated from the core connection circuit and is configured to transmit a power supply voltage.

2. The stacked memory device of claim 1,
wherein the base die comprises a base interconnection and a base through via set;
wherein the base interconnection comprises a plurality of metal layers, and
wherein the base through via set comprises a plurality of through vias.

3. The stacked memory device of claim 1,
wherein the core interconnection comprises a plurality of metal layers, and
wherein the core through via set comprises a plurality of through vias.

4. The stacked memory device of claim 1, wherein the core connection circuit is configured to transmit electrical signals comprising commands, addresses, control signals, and the power supply voltage to one of the base die and the plurality of core dies using the core interconnection and the core through via set.

5. The stacked memory device of claim 1, wherein the isolated connection circuit comprises an isolated interconnection and an isolated through via.

6. The stacked memory device of claim 5,
wherein the isolated interconnection comprises a plurality of metal layer, and
wherein the isolated through via comprises a plurality of through vias.

7. The stacked memory device of claim 5, wherein the power supply voltage is transmitted to the power supply wire through the plurality of core dies using the isolated interconnection and the isolated through via.

8. The stacked memory device of claim 7, wherein the power supply wire supplies the power supply voltage transmitted using the isolated interconnection and the isolated through via to the plurality of core dies.

9. The stacked memory device of claim 1, wherein the plurality of core dies comprise a first core die and a second core die, and
wherein the first core die is stacked over the base die, the second core die is stacked over the first core die, and the power supply wire is stacked over the second core die.

10. The stacked memory device of claim 9, wherein the first core die comprises:
a first core connection circuit; and
a first isolated connection circuit that is separated from the first core connection circuit and is configured to transmit the power supply voltage.

11. The stacked memory device of claim 10, wherein the second core die comprises:
a second core connection circuit; and
a second isolated connection circuit that is separated from the second core connection circuit and is configured to transmit the power supply voltage.

12. The stacked memory device of claim 11, wherein the power supply wire is configured to:
receive the power supply voltage through the first isolated connection circuit and the second isolated connection circuit,
supply the power supply voltage to the first core die through the first core connection circuit, and
supply the power supply voltage to the second core die through the second core connection circuit.

13. A stacked memory device comprising:
a plurality of core dies stacked over a base die; and
a power supply wire stacked over the plurality of core dies,
wherein the base die comprises:
a base connection circuit comprising a base interconnection and a base through via set; and
a base isolated connection circuit that is separated from the base connection circuit and is configured to transmit a power supply voltage, and
wherein each of the plurality of core dies comprises:
a core connection circuit comprising a core interconnection and a core through via set; and
an isolated connection circuit that is separated from the core connection circuit and is configured to transmit the power supply voltage.

14. The stacked memory device of claim 13, wherein the base connection circuit is configured to transmit electrical signals comprising commands, addresses, control signals, and the power supply voltage to the plurality of core dies using the base interconnection and the base through via set.

15. The stacked memory device of claim 13, wherein the core connection circuit is configured to transmit electrical signals comprising commands, addresses, control signals, and the power supply voltage to one of the base die and the plurality of core dies using the core interconnection and the core through via set.

16. The stacked memory device of claim 13, wherein the power supply voltage is transmitted to the power supply wire through the plurality of core dies using the base isolated connection circuit and the isolated connection circuit.

17. The stacked memory device of claim 13, wherein the plurality of core dies comprise a first core die and a second core die, and
wherein the first core die is stacked over the base die, the second core die is stacked over the first core die, and the power supply wire is stacked over the second core die.

18. The stacked memory device of claim 17,
wherein the first core die comprises:
a first core connection circuit; and
a first isolated connection circuit that is separated from the first core connection circuit and is configured to transmit the power supply voltage, and
wherein second core die comprises:
a second core connection circuit; and
a second isolated connection circuit that is separated from the second core connection circuit and is configured to transmit the power supply voltage.

19. The stacked memory device of claim 18, wherein the power supply wire is configured to:
receive the power supply voltage through the base isolated connection circuit, the first isolated connection circuit, and the second isolated connection circuit,
supply the power supply voltage to the first core die through the first core connection circuit, and
supply the power supply voltage to the second core die through the second core connection circuit.

20. A stacked memory device comprising:
a plurality of core dies stacked over a base die,
wherein the base die comprises:
a base connection circuit comprising a base interconnection and a base through via set; and
a base isolated connection circuit that is separated from the base connection circuit and is configured to transmit a power supply voltage.

21. The stacked memory device of claim 20, wherein the base connection circuit is configured to transmit electrical signals comprising commands, addresses, control signals, and the power supply voltage to the plurality of core dies using the base interconnection and the base through via set.

22. The stacked memory device of claim 20, wherein the power supply voltage is transmitted to the plurality of core dies through the base isolated connection circuit.
